(19) United States
(12) Patent Application Publication
(10) Pub. No.: US 2009/0304906 A1
(43) Pub. Date: Dec. 10, 2009

(54) EVAPORATING APPARATUS, APPARATUS FOR CONTROLLING EVAPORATING APPARATUS, METHOD FOR CONTROLLING EVAPORATING APPARATUS, METHOD FOR USING EVAPORATING APPARATUS AND METHOD FOR MANUFACTURING BLOWING PORT

(75) Inventors: Kenji Suduo, Hyogo (JP); Hiroyuki Ikuta, Hyogo (JP); Noriaki Fukiage, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/443,269

(22) PCT Filed: Oct. 1, 2007
(86) PCT No.: PCT/JP2007/069167

§ 371 Date: Mar. 27, 2009

(30) Foreign Application Priority Data
Sep. 29, 2006 (JP) 2006-269100

(51) Int. Cl. C23C 14/24; B23P 17/00; C23C 14/54

(52) U.S. Cl. 427/8; 29/592; 427/248.1; 118/726; 118/667

(57) ABSTRACT

An evaporating apparatus 10 includes a vapor deposition source 210, a transport path 110e21, a blowing vessel 110 and a first processing chamber 100. The transport path 110e21 is connected with the vapor deposition source 210 via a connection path 220e and transports a film forming material vaporized from the vapor deposition source 210. A blowing port 110e11 is formed of a metal porous member and blows out the film forming material which has passed through a buffer space S via the transport path 110e21. The first processing chamber 100 performs the film formation on a target object G with the blown-out film forming material. A gap between the target object G and the blowing port 110e1 can be shortened by blowing out gas molecules having a high uniformity from the metal porous member.

### TECHNICAL FIELD

The present invention relates to an evaporating apparatus, an apparatus for controlling the evaporating apparatus, a method for controlling the evaporating apparatus, a method for using the evaporating apparatus, and a method for manufacturing a blowing port. More particularly, the present invention relates to an evaporating apparatus featuring high utilization efficiency of material and a control method therefor.

### BACKGROUND ART

Widely employed in a manufacturing process of an electronic device such as a flat panel display or the like is an evaporating method for forming a film on a target object by adhering gas molecules, which is generated as a result of vaporizing a preset film forming material, to the target object. Among various types of devices manufactured by using such evaporating technology, an organic EL display is particularly known to be superior to a liquid crystal display for the reason of its self-luminescence, high reaction speed, low power consumption and so forth. Accordingly, an increasing demand for the organic EL display is expected from now on, and, particularly, it is attracting high attention in the field of manufacture of the flat display panel which is expected to be scaled-up. Thus, the evaporating technology employed in the manufacture of the organic EL display is deemed to be very important.

The evaporating technology which is attracting attention in such technical background is implemented by an evaporating apparatus. With regard to this evaporating apparatus, there have been employed two types of vapor deposition sources: one is a point source type vapor deposition source for adhering gas molecules to a substrate by blowing the gas molecules from a dot-shaped opening provided at the vapor deposition source; and the other is a linear source type vapor deposition source for adhering gas molecules to a substrate by blowing the gas molecules from a rectangular opening or an opening formed by arranging a plurality of point source type vapor deposition sources in an array (see, for example, Non-patent Document 1).

As for the liner source type evaporating apparatus having the rectangular opening among the above-mentioned evaporating apparatuses, in case that there is a plurality of film forming materials to be used as source materials for film formation, gas molecules of the respective film forming materials need to be adhered to a substrate after being mixed with each other uniformly in order to achieve high-quality and uniform film formation. Therefore, in the conventional evaporating apparatus, a gap between a blowing port for discharging the film forming material and a target object is increased enough to allow the gas molecules of the different film forming materials to be diffused and mixed sufficiently until they reach the target object after being discharged from the blowing port (see, for example, Patent Document 2).

Non-patent Document 1: Organic EL display Illumination 2005 thorough verification (held on Jun. 28, 2005)

Sponsor: Electronic journal, Preliminary notice collection of lectures, pp. 32 to 34

Patent Document 2: Japanese Patent Laid-open Publication No. 2001-291589

### DISCLOSURE OF THE INVENTION

### Means for Solving the Problems

However, if a gap between a blowing port and a target object is increased, the range of a diffusion of gas molecules during their movement from the blowing port to the target object is enlarged as well. In this way, if the gas molecules are moved while being diffused beyond a vapor deposition surface of the target object, an amount of film forming material (gas molecules) exhausted without being adhered to the target object increases, so that utilization efficiency of material deteriorates, resulting in an increase of manufacturing cost.

Further, gas molecules which are not adhered to a substrate may be adhered to other parts inside a processing chamber. In such case, a cleaning cycle for the inside of the processing chamber is shortened, resulting in deterioration of throughput and productivity.

In view of the foregoing, the present invention provides a novel and advanced evaporating apparatus featuring high utilization efficiency of material, and also provides an apparatus and method for controlling the evaporating apparatus and a method for using the evaporating apparatus.

To solve the above-mentioned problems, in accordance with one aspect of the present invention, there is provided an evaporating apparatus including: a vapor deposition source for vaporizing a film forming material which is a source material for a film formation; a transport path connected with the vapor deposition source via a connection path, for transporting the film forming material vaporized from the vapor deposition source; a blowing vessel having a blowing port connected with the transport path, for blowing out the film forming material transported through the transport path from the blowing port; and a processing chamber for performing the film formation on a target object with the blown-out film forming material.

Here, the term “vaporization” or “evaporation” implies not only the phenomenon that a liquid is converted into a gas but also a phenomenon that a solid is directly converted into a gas without becoming a liquid (i.e., sublimation).

The blowing vessel has a buffer space therein, and blows out the film forming material from the blowing port after the film forming material passes through the buffer space such that a pressure in the buffer space of the blowing vessel becomes higher than a pressure outside the blowing vessel.

It is deemed that, in case that a pressure in the buffer space of the blowing vessel is higher than a pressure outside the blowing vessel, the following phenomenon occurs in vicinity of the blowing port. That is, at least a part of the gas molecules present inside the blowing vessel is not allowed to pass through the blowing port smoothly but reflected from the inner wall of the blowing vessel and rebounded into the buffer space. After such movements are repeated, the gas molecules are allowed to be discharged out through the opening of the blowing port. That is, among the gas molecules that have been introduced into the buffer space through the connection pipe and the transport path after vaporized from the vapor deposition source, gas molecules exceeding a preset amount cannot pass through the blowing port immediately, and they stay in the buffer space temporarily. In this way, the pressure (density) inside the buffer space is maintained higher than the pressure (density) outside the blowing vessel. Accordingly, while the gas molecules are staying in the buffer space, they are mixed with each other to be in a uniform state.

As a result, the gas molecules are blown out from the blowing port in a uniform state, whereby uniform fine-quality film can be formed on the target object by using the gas molecules having the high controllability of the film formation even in case that the gap between the blowing port and the target object is greatly shortened in comparison with conventional cases.

Further, by shortening the gap between the blowing port of the blowing vessel and the target object, excessive diffusion of the gas molecules blown out from the blowing port is suppressed, so that a greater amount of gas molecules can be adhered to the vapor deposition surface of the target object, resulting in improvement of the material utilization efficiency. In consequence, manufacturing cost of a product is reduced.

Furthermore, by suppressing the excessive diffusion of the gas molecules as described above, the gas molecules are suppressed from adhering to other parts inside the processing chamber. Thus, the cleaning cycle for the inside of the processing chamber can be lengthened, so that throughput and productivity can be enhanced.

The blowing port may be formed of a porous body. Further, the blowing port may have a practical width Wp in a range of α mm±α×0.01 mm when a goal width Wg of a shorter-side of the blowing port is set as α mm, and a length lo of a longer-side of the opening, the length lo being longer than a length ls of the target object, which is positioned above the blowing vessel, in a direction horizontal to a lengthwise direction of the opening by at least ls×0.1 mm at both ends of the blowing port.

It is desirable that, in case that the blowing port is formed of a porous body, the porosity of the porous body is equal to or less than about 97%. For example, if the porosity is 97%, the particle diameter of the porous body becomes about 600 μm. When the gas molecules pass through the porous body having the particle diameter equal to or less than 600 μm, the gas molecules collide with the wall surface of the flow paths (void spaces between the pores) inside the porous body or other gas molecules and are uniformly blown out from the entire surface of the blowing port in a state in which their directional deflection is low, while their velocity gets reduced. Accordingly, the gas molecules of the film forming material may be blown out from the entire surface of the blowing port after sufficiently mixed with each other.

Further, in case that the blowing port has a preset slit shape, if the accuracy of the slit width is improved such that the practical value Wp of the width (shorter-side) of the slit-shaped opening is set to be in a range of α mm±α×0.01 mm (α mm is the goal width value Wg), the gas molecules can be blown out from the slit-shaped opening uniformly. Particularly, it is desirable that the α mm as the goal width value Wg of the slit-shaped opening is set to be equal to or smaller than about 3 mm.

Furthermore, it is desirable that a length lo of a longer-side of the slit opening is longer than a length ls (see FIG. 10) of the target object, which is positioned above the blowing vessel, in a direction horizontal to a lengthwise direction of the opening by at least ls×0.1 mm at both ends thereof.

In this way, by setting the length of the slit opening to be longer than the length of the target object by 10% at both ends of the slit opening, the amount of organic molecules diffused up to the outer periphery portion of the target object can be maintained to be substantially equal to the amount of the organic molecules diffused to the other position of the target object when the organic molecules (gas molecules of the film forming material) are diffused in a length direction of the slit opening. As a result, a uniform thin film having fine quality can be formed on the target object.

The transport path may be branched into a plurality of transport paths, and the branched transport paths may have same lengths. The velocity decrease of the gas molecules of the film forming material due to collision with the wall surface of the transport path or other gas molecules during their travel through the transport path is in proportion to the length of the transport path through which the gas molecules pass. Accordingly, by setting the lengths of the branched transport paths to be all same, the gas molecules can be blown out from respective openings of the branched transport paths toward the buffer space at a substantially same velocity.

At this time, openings of the branched transport paths may be equi-spaced with respect to a preset direction. Further, the branched transport paths may be formed point-symmetrically with respect to a branch position of the transport paths. In this configuration, the gas molecules are uniformly discharged out from the openings of the transport paths arranged at the same distance toward the buffing space after passing through the transport paths having the same structure point-symmetrically. Accordingly, the gas molecules can be more uniformly discharged out toward the buffer space at a substantially same velocity. As a result, the gas molecules can be maintained in a more uniform state in the buffer space of the blowing vessel.

The evaporating apparatus may further include a diffusion plate which partitions the buffer space of the blowing vessel into a blowing port side space and a transport path side space and allows the film forming material to pass therethrough. The diffusion plate may be a partition plate formed of a porous body or a partition plate provided with a number of holes such as, e. g, a punching metal.

With this configuration, the buffer space is partitioned into the blowing port side space and the transport path side space by the diffusion plate. In this manner, the gas molecules discharged into the buffer space is always made to pass through the diffusion plate and then moved to the blowing port side space from the transport path side space. In this way, the gas molecules can be further mixed when passing through the diffusion plate and also a pressure in the blowing port side space can be further stabilized by the diffusion plate. As a result, the gas molecules can be blown out from the blowing port more uniformly. Thus, the controllability of the film formation increases, so that a uniform film with a fine quality can be formed on the target object even if the gap between the blowing vessel and the target object is set to be shorter than that in conventional cases.

Each of the blowing port of the porous body and the diffusion plate may be made of a conductive member. Further, the blowing port of the porous body and the diffusion plate may include temperature control mechanisms for controlling temperatures of the blowing port and the diffusion plate.

In this way, the blowing port and the diffusion plate are made of a conductive member such as, e.g., a metal, and a temperature control mechanism such as a heater is installed at the blowing port and the diffusion plate, whereby the entire regions of the blowing port and the diffusion plate can be maintained at high temperatures by way of heating the blowing port and the diffusion plate with the heaters or the like and transferring the heat to the entire regions of the blowing port and the diffusion plate.

Here, according to the disclosure of a book titled “Thin Film Optics” (published by Murata Seishiro, Maruzen Inc., 1^{st} edition on Mar. 15, 2003 and 2^{nd} edition on Apr. 10, 2004), vaporized molecules (gas molecules of the film forming materials) that have reached the target object are not adhered to the substrate and accumulated thereon just as they are in a manner that they are fallen and stacked to form a film, but a part of them is reflected and rebounded into the vacuum. Further, some of the molecules adhered on the surface of the substrate keep moving on the surface; some of them are bound again into the vacuum; and some of them are caught in sites on the target object to form a film. An average time of the molecules kept in an adsorption state (average residence time τ) is indicated by an equation of τ=τ₀exp(Ea/kT), wherein Ea represents an activation energy for the escape.

Since T is an absolute temperature; k, a Boltzmann constant; and τ₀, a predetermined constant, the average residence time τ is deemed to be a function of the absolute temperature T. This equation indicates that the number of the gas molecules physically adhered to a transport path decreases with the increase of the temperature.

As described above, as the temperatures of the members (e.g., the blowing port and the diffusion plate) through which the gas molecules pass are set to be higher, the number of gas molecules adhered to those members decreases while they are passing through such members. As a result, most of the gas molecules can be allowed to adhere to the target object without adhering to the blowing port or the diffusion plate. Thus, the material utilization efficiency can be further improved.

Furthermore, the vapor deposition source may include a temperature control mechanism for controlling a temperature of the vapor deposition source. In this configuration, the temperature of the vapor deposition source can be controlled by using the temperature control mechanism installed at the vapor deposition source so as to further reduce the number of the gas molecules of the film forming materials adhered to the vapor deposition source or the connection path after vaporized from the vapor deposition source. As a result, the material utilization efficiency can be further improved.

Specifically, the temperature control mechanism of the vapor deposition source may include a first temperature control mechanism and a second temperature control mechanism, the first temperature control mechanism may be disposed on the side of the film forming material accommodating portion of the vapor deposition source, so as to maintain a temperature of the film forming material accommodating portion to a predetermined temperature, and the second temperature control mechanism may be disposed at a vapor deposition source's outlet portion, from which the film forming material is discharged, so as to maintain a temperature of the outlet portion to be higher than or equal to the temperature of the film forming material accommodating portion.

An example of the first temperature control mechanism installed at the vapor deposition source's film forming material accommodating portion may be a first heater embedded in a bottom wall of the vapor deposition source where the film forming material is stored (see, for example, 400e1 in FIG. 2). Further, an example of the second temperature control mechanism installed on the vapor deposition source's outlet side from which the film forming material is discharged may be a second heater (see, for example, 410e1 in FIG. 2) embedded in the sidewall of the vapor deposition source. As an example of a temperature control using the first and second heaters, a voltage applied to the second heater from a power supply may be set to be higher than that applied to the first heater. In this way, the temperature of the vicinity (indicated by r in FIG. 2) of an outlet of each crucible from which the vaporized film forming material is blown out can be increased higher than the temperature of the vicinity of the vapor deposition source's film forming material accommodating portion (indicated by q in FIG. 2). As a result, the number of the gas molecules adhered to the vapor deposition source or the connection path is further reduced while the film forming materials are being flown toward the blowing vessel, so that the material utilization efficiency can be improved.

More than one vapor deposition source may be installed; different kinds of film forming materials may be accommodated in the vapor deposition sources, respectively; connection paths respectively connected with the vapor deposition sources may be coupled at a preset junction position; and based on the amounts of the different kinds of film forming materials vaporized from the vapor deposition sources per unit time, a flow path adjusting member (for example, orifice) may be installed in one of the connection paths at an upstream position of the preset junction position to control a flow path of the one connection path.

For example, based on the amounts of the different kinds of film forming materials vaporized from the vapor deposition sources per unit time, the flow path adjusting member may be installed in the connection path through which the film forming material having a low vaporization rate per unit time passes.

When the connection paths have the same diameters, an internal pressure of the connection path through which the film forming material, vaporized from the vapor deposition source, having a high vaporization rate (molecule amount per unit time) passes becomes higher than an internal pressure of the connection path through which the film forming material having a low vaporization rate passes. Accordingly, the gas molecules tend to be introduced from the connection path having the higher internal pressure into the connection path having the lower internal pressure.

However, based on the vaporization rate of film forming materials vaporized from the vapor deposition sources, the flow path adjusting member is installed in the connection path through which the film forming material having a low vaporization rate passes. For example, if an orifice (partition plate) having a central opening is used as the flow path adjusting member, the flow path are narrowed at the position where the orifice is installed, so that the passage of the gas molecules is limited.

In this configuration, the gas molecules of the film forming material can be prevented from being introduced toward the connection path having the lower internal pressure from the connection path having the higher internal pressure. In this way, by introducing the gas molecules of various film forming materials toward the blowing vessel while preventing their backflow, a greater amount of gas molecules can be deposited on the target object, so that the material utilization efficiency can be further improved.

More than one blowing vessel may be installed, and the processing chamber may accommodate the blowing vessels therein, and a plurality of film forming processes may be consecutively performed on the target object with the film forming materials blown out from the respective blowing vessels in the processing chamber.

In accordance with the present invention, a plurality of films is consecutively formed within the same processing chamber. Thus, the throughput can be enhanced and the productivity can be improved. Furthermore, since a plurality of processing chambers needs not to be installed separately for each of the films to be formed as in a conventional case, the scale-up of the equipment is suppressed, and cost therefor can be reduced.

Further, the processing chamber may form an organic EL film or an organic metal film on the target object by vapor deposition by using an organic EL film forming material or an organic metal film forming material as a source material.

Furthermore, more than one vapor deposition source may be installed, and a plurality of first sensors corresponding to the vapor deposition sources may be disposed to detect respective vaporization rates of film forming materials accommodated in the vapor deposition sources.

Accordingly, the temperature of each vapor deposition source can be controlled with high accuracy based on the vaporization rate of each film forming material (simple substance) outputted from the first sensor. As a result, by allowing the vaporization rate of the film forming material contained in each vapor deposition source to be approximate to a target value more accurately, a ratio of the mixture of gas molecules blown out from the blowing mechanism can be controlled with higher accuracy. As a consequence, the controllability of the film formation can be improved, and a more uniform thin film having better quality can be formed on the target object.

A second sensor corresponding to the blowing vessel may be disposed in a first processing chamber to detect a film forming rate of the film forming material blown out from the blowing vessel.

With this configuration, it is possible to detect the film forming rate of film forming materials mixed in the buffer space of the blowing vessel by using the second sensor while concurrently detecting the vaporization rate of each film forming material (simple substance) contained in each vapor deposition source by using the first sensors. Accordingly, it is possible to measure the loss amount of the gas molecules as a result of their adherence while they are travelling from the vapor deposition source to the blowing vessel through the connection path and the transport path. Thus, the temperature of each vapor deposition source can be controlled more accurately based on the vaporization rates of various kinds of film forming materials (simple substances) and the film forming rate of the mixture of film forming materials. Accordingly, the controllability of the film formation can be improved, and a more uniform thin film having a better quality can be formed on the target object. Further, as long as the first sensors are provided, installation of the second sensor is optional.

Further, to control a temperature of each vapor deposition source based on the vaporization rate of each film forming material (simple substance) outputted from each sensor, a QCM (Quartz Crystal Microbalance) is used, for example. Below, the simple principle of the QCM will be explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed as described above is a QCM. As can be seen from the equation, a change of the frequency is deemed to be determined based on a change of the elastic constant dependent on the adhered substance; and a thickness dimension of the adhered substance calculated in terms of the quartz density. Thus, the change of the frequency can be calculated in terms of the weight of the deposits.

To solve the above-mentioned problems, in accordance with another aspect of the present invention, there is provided a control apparatus for controlling the evaporating apparatus, which feedback controls a temperature of a temperature control mechanism installed at each vapor deposition source based on the respective vaporization rates of the film forming materials detected by the first sensors.

Further, to solve the above-mentioned problems, in accordance with still another aspect of the present invention, there is provided a control method for controlling the evaporating apparatus, which feedback controls a temperature of a temperature control mechanism installed at each vapor deposition source based on the respective vaporization rates of the film forming materials detected by the first sensors.

In this way, the temperature of each vapor deposition source can be controlled with high accuracy in real time, based on the vaporization rates of the different kinds of film forming materials (simple substances) detected by the first sensors. As a result, by allowing the vaporization rate of the film forming material to be approximate to a target value more accurately, a ratio of the mixture of gas molecules blown out from the blowing mechanism can be controlled with higher accuracy. As a consequence, the controllability of the film formation can be improved, and a more uniform thin film having a better quality can be formed on the target object.

Further, by feedback controlling the temperature of the temperature control mechanism installed at every vapor deposition source such that the temperature of the vapor deposition source's outlet portion from which the vaporized film forming material is discharged is set to be higher than or equal to the temperature of the vapor deposition source's film forming material accommodating portion, the number of the gas molecules adhered to the vapor deposition source or the connection path is further reduced while the film forming materials are being flown toward the blowing mechanism, so that the material utilization efficiency can be improved.

Further, to solve the above-mentioned problems, in accordance with still another aspect of the present invention, there is provided a method for using an evaporating apparatus, the method including: vaporizing the film forming material accommodated in the vapor deposition source; passing the vaporized film forming material through the buffer space installed in the blowing vessel via the connection path and the transport path; blowing out the film forming material, which has passed through the buffer space, from the blowing port of a porous body in the blowing vessel; and performing the film formation on the target object with the blown film forming material in the processing chamber.

Further, to solve the above-mentioned problems, in accordance with still another aspect of the present invention, there is provided a method for using an evaporating apparatus, the method including: vaporizing the film forming material accommodated in the vapor deposition source; passing the vaporized film forming material through the buffer space installed in the blowing vessel via the connection path and the transport path; blowing out the film forming material, which has passed through the buffer space, from the blowing port installed in the blowing vessel such that a pressure in the buffer space of the blowing vessel becomes higher than a pressure outside the blowing vessel; and performing the film formation on the target object with the blown film forming material in the processing chamber.

Furthermore, in accordance with still another aspect of the present invention, there is provided a method for manufacturing a blowing port provided in a blowing vessel for blowing out a film forming material vaporized from a vapor deposition source, wherein the method makes a shape of the blowing port such that a practical width Wp is in a range of α mm±α×0.01 mm when a goal width Wg of a shorter-side of a slit-shaped opening of the blowing port is set as α mm, and a length lo of a longer-side of the opening is longer than a length ls of a target object in a direction horizontal to a lengthwise direction of the opening by at least ls×0.1 mm at both ends of the opening.

In accordance with this method, the gas molecules of the film forming material are blown out from the slit-shaped blowing port having, for example, a preset accuracy and a preset shape, so that the blown amount of the gas molecules is limited. In this way, among the gas molecules that have been introduced into the buffer space through the connection pipe and the transport path after vaporized from the vapor deposition source, gas molecules exceeding a preset amount cannot immediately pass through the blowing port having the porous body or a preset slit shape, and they stay in the buffer space temporarily. As a result, the pressure (density) inside the buffer space is maintained higher than the pressure (density) outside the blowing vessel. Accordingly, while the gas molecules are staying in the buffer space, they are mixed with each other to be in a uniform state.

Further, the accuracy of the slit width is improved such that the practical value Wp of the width (shorter-side) of the slit opening is set to be in the range of α mm±α×0.01 mm (α mm is the goal width value Wg), so that the gas can be blown out very uniformly in the lengthwise direction of the opening.

Furthermore, a shape of the blowing port is formed such that a length lo of a longer-side of the opening is longer than a length ls of the target object, which is positioned above the blowing vessel, in a direction horizontal to a lengthwise direction of the opening by at least ls×0.1 mm at both ends thereof, so that the amount of organic molecules diffused up to the outer periphery portion of the target object can be maintained to be substantially equal to the amount of the organic molecules diffused to the other position of the target object when the organic molecules are diffused in a length direction of the opening. As a result, a uniform thin film having a fine quality can be formed on the target object.

In accordance with the present invention stated so far, it is possible to provide a novel and advanced evaporating apparatus having a high material utilization efficiency; a control apparatus and a control method for controlling the evaporating apparatus; a method for using the evaporating apparatus; and a method for manufacturing a blowing port.

### BRIEF DESCRIPTION OF THE DRAWINGS

FIG. 1 provides a perspective view of major components of an evaporating apparatus in accordance with a first embodiment of the present invention;

FIG. 2 sets forth a cross sectional view of the evaporating apparatus in accordance with the first embodiment of the present invention taken along a line A-A of FIG. 1;

FIG. 3 presents a diagram showing a diffusion plate in accordance with the first embodiment of the present invention;

FIG. 4 offers a diagram showing a blowing vessel in accordance with the first embodiment of the present invention;

FIG. 5 depicts a diagram for describing a film formed by a 6-layer consecutive film forming process in accordance with the first embodiment of the present invention;

FIG. 6 sets forth a graph showing a relationship between temperature and adhesion coefficient;

FIG. 7 illustrates a chart showing processing conditions for an experiment using the evaporating apparatus in accordance with the first embodiment of the present invention;

FIG. 8 is a graph showing an experiment result concerned with reliability in case of using the evaporating apparatus in accordance with the first embodiment of the present invention;

FIG. 9 sets forth a graph showing an experiment result in case of varying porosity of a porous material of a blowing port in the evaporating apparatus in accordance with the first embodiment of the present invention;

FIG. 10 presents a perspective view of major components of an evaporating apparatus in accordance with a second embodiment of the present invention;

FIG. 11 provides a cross sectional view of the evaporating apparatus in accordance with the second embodiment of the present invention taken along a line A-A of FIG. 1;

FIG. 12 depicts a plan view of a blowing port in accordance with the second embodiment of the present invention;

FIG. 13 sets forth a diagram for describing an experiment using the blowing port in accordance with the second embodiment of the present invention;

FIG. 14 provides a chart showing experiment data related to accuracy of shorter-side length of the blowing port in accordance with the second embodiment of the present invention;

FIG. 15 is a chart showing normalized data of each slot width of FIG. 14; and

FIG. 16 presents a graph showing an experiment result in case of varying the longer-side length of the blowing port in accordance with the second embodiment of the present invention.

### EXPLANATION OF CODES

10: Evaporating apparatus
100: First processing chamber
110, 110a˜110f: Blowing vessels
110e1: Blowing mechanism
110e11, 110e17: blowing ports
110e12: Frame
110e13: Diffusion plate
110e16: Orifice
110e2: Transport mechanism
110e21: Transport path
200: Second processing chamber
210, 210a˜210f: Vapor deposition sources
210e1: First crucible
210e13: Orifice
210e2: Second crucible
210e23: Orifice
210e3: Third crucible
210e33: Orifice
220e, 220e1˜220e3: Connection pipes
230e1˜230e3: Valves
240e2, 240e3: Orifices
300, 310: QCMs
400e, 410e, 420e, 430e: Heaters
700: Controller
S: Buffer space

### BEST MODE FOR CARRYING OUT THE INVENTION

### First Embodiment

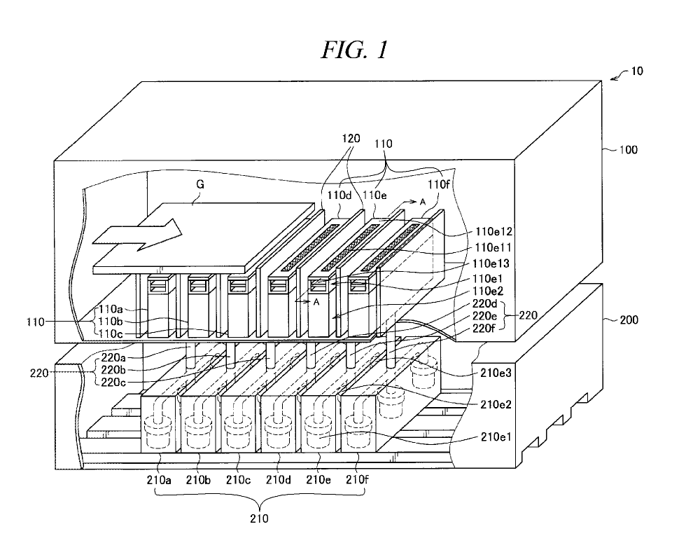

First, an evaporating apparatus in accordance with a first embodiment of the present invention will be described with reference to FIG. 1, which provides a perspective view showing major components of the evaporating apparatus. The following description is provided for the example case of manufacturing an organic EL display by consecutively depositing 6 layers including an organic EL layer in sequence on a target object (hereinafter simply referred to as “substrate”) by using the evaporating apparatus.

Further, parts having the same configurations and functions will be assigned like reference numerals in the following description and the accompanying drawings, and redundant description thereof will be omitted. Further, in the present document, it is assumed that 1 mTorr is (10⁻³×101325/760) Pa, and 1 sccm is (10⁻⁶/60) m³/sec.

(Evaporating Apparatus)

The evaporating apparatus 10 includes a first processing chamber 100 and a second processing chamber 200. Below, the shape and internal configuration of the first processing chamber 100 will be first explained, and the shape and internal configuration of the second processing chamber 200 will be described later.

(First Processing Chamber)

The first processing chamber 100 has a rectangular parallelepiped shape and incorporates a first blowing vessel 110a, a second blowing vessel 110b, a third blowing vessel 110c, a fourth blowing vessel 110d, a fifth blowing vessel 110e and a sixth blowing vessel 110f. Inside the first processing chamber 100, film formation processes are consecutively performed on the target object G by gas molecules blown out from the six blowing vessels 110. The first processing chamber 100 is a processing chamber for performing a film formation on the target object G by using a film forming material vaporized from a vapor deposition source.

The six blowing vessels 110 are arranged in parallel to each other at a same distance therebetween such that their lengthwise directions become substantially perpendicular to the advancing direction of the target object G. Partition walls 120 are disposed between the respective blowing vessels 110. By separating the blowing vessels 110 with the seven partition walls 120, gas molecules of a film forming material blown out from each blowing vessel 110 can be prevented from being mixed with gas molecules blown out from adjacent blowing vessels 110.

Each blowing vessel 110 has a length approximately equal to the width of the target object G, and they have the same shape and configuration. Thus, the internal configuration of the fifth blowing vessel 110e will only be explained for example, while omitting description of the other blowing vessels 110.

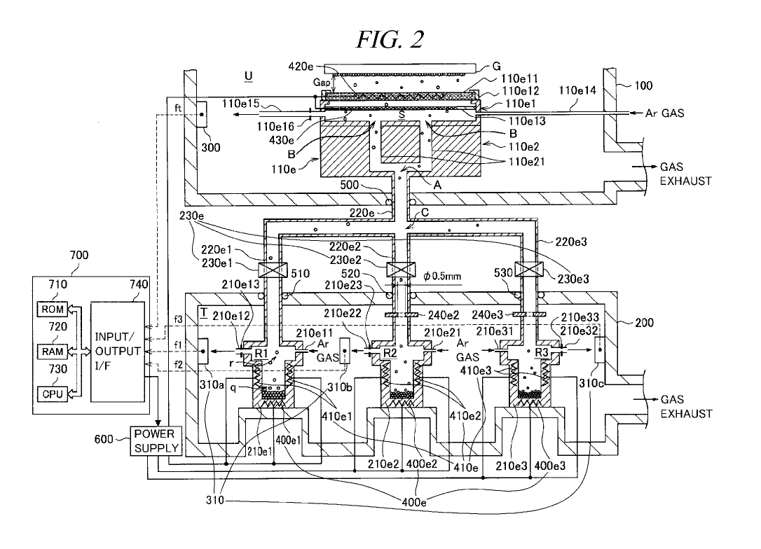

As can be seen from FIG. 1 and FIG. 2 which is a cross sectional view of the evaporating apparatus 10 taken along a line A-A of FIG. 1, the fifth blowing vessel 110e includes a blowing mechanism 110e1 in its upper portion and a transport mechanism 110e2 in its lower portion. The blowing mechanism 110e1, of which an inside is hollow (hereinafter, this inside will be referred to as “buffer space S”), has a blowing port 110e11 and a frame 110e12 at its top portion. A diffusion plate 110e13 is provided inside the buffer space S.

The blowing port 110e11 is made of a metal porous member. The metal porous member is a metal porous body, and pores therein are interconnected. It has a pore diameter (hole diameter) of about 150 μm and a porosity of about 87%. The blowing port 110e11 blows out the vaporized film forming material toward the target object G by allowing the vaporized film forming material to pass through void spaces between the pores in the metal porous member. Further, though it is desirable to set the porosity of the metal porous member to be equal to or lower than about 97%, optimization of the porosity will be further described later. A heater 420e for controlling the temperature of the blowing port 110e11 is embedded in the blowing port 110e11. An AC power supply 600 is connected with the heater 420e.

The frame 110e12 has a rectangular central opening through which the metal porous member of the blowing port 110e11 is exposed, as shown in FIG. 1, and fixes the blowing port 110e11 at the peripheral portion of the blowing port 110e11 with screws.

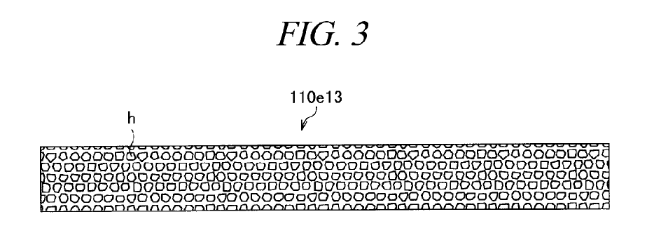

The diffusion plate 110e13 is installed in parallel with the metal porous member of the blowing port 110e11 so as to divide the buffer space S into a space at the blowing port 110e11 and a space at a transport path 110e21 to be described later. As illustrated in FIG. 3 which provides a plan view of the diffusion plate 110e13, the diffusion plate 110e13 is a partition plate provided with a plurality of holes, e.g., a punching metal provided with a plurality of holes h formed by punching a metal plate. Further, the diffusion plate 110e13 may be formed of a porous material such as a metal porous member (not shown).

Referring back to FIG. 2, a heater 430e for controlling the temperature of the diffusion plate 110e13 is embedded in the diffusion plate 110e13. The AC power supply 600 is connected with the heater 430e.

Since each of the blowing port 110e11 and the diffusion plate 110e13 is formed of a conductive member such as a metal or the like, the entire regions of the blowing port 110e11 and the diffusion plate 110e13 can be maintained at high temperatures by way of heating the blowing port 110e11 and the diffusion plate 110e13 with the heaters 420e and 430e and transferring the heat to the entire regions of the blowing port 110e11 and the diffusion plate 110e13.

Here, according to the disclosure of a book titled “Thin Film Optics” (published by Murata Seishiro, Maruzen Inc., 1^{st} edition on Mar. 15, 2003 and 2^{nd} edition on Apr. 10, 2004), vaporized molecules (gas molecules of the film forming materials) that have reached the target object are not adhered to the target object and accumulated thereon just as they are in a manner that they are fallen and stacked to form a film, but a part of them is reflected and rebounded into the vacuum. Further, some of the molecules adhered on the surface of the substrate keep moving on its surface; some of them are bound again into the vacuum; and some of them are caught in sites on the target object to form a film. An average time of the molecules kept in an adsorption state (average residence time τ) is expressed by an equation of τ=τ₀exp(Ea/kT), wherein Ea represents an activation energy for the escape.

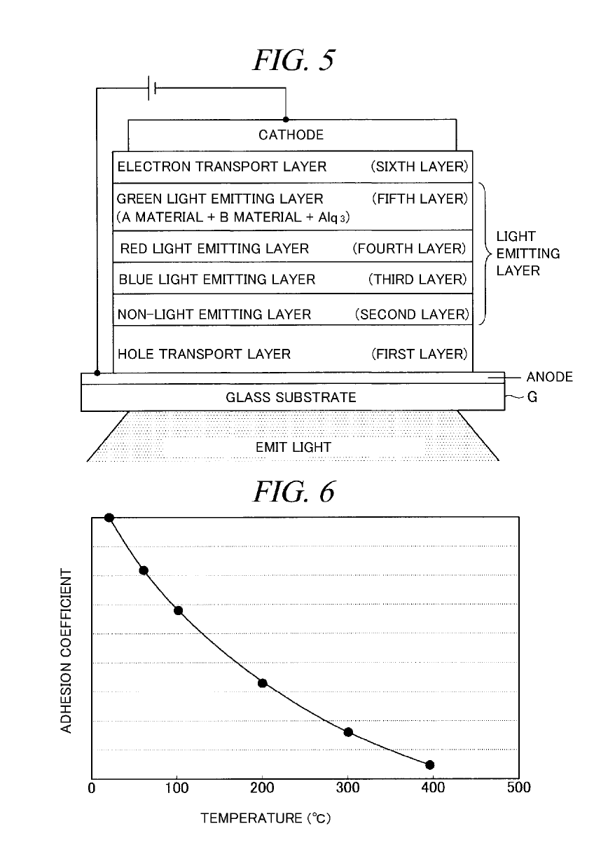

Since T is an absolute temperature; k, a Boltzmann constant; and τ₀, a predetermined constant, the average residence time τ is deemed to be a function of the absolute temperature T. The present inventors conducted calculations to investigate the relationship between temperature and adhesion coefficient. Here, α-NPD (diphenyl naphthyl diamine: an example of an organic material) was used as an organic material, and the calculation result is provided in FIG. 5. As can be seen from the result, it is found that the adhesion coefficient decreases with the increase of the temperature (° C.). That is, the result indicates that the number of gas molecules physically adhered to the transport path or the like decreases with the increase of the temperature.

That is, as the temperatures of the members (e.g., the blowing port 110e11 and the diffusion plate 110e13) through which the gas molecules pass are set to be higher, the number of gas molecules adhered to those members decreases while they are passing through such members. As a result, most of the gas molecules can be allowed to adhere to the target object G without adhering to the blowing port 110e11 or the diffusion plate 110e13. Thus, the material utilization efficiency can be further improved.

The blowing mechanism 110e1 is provided with a supply pipe 110e14 inserted through the sidewalls of the first processing chamber 100 and the blowing mechanism 110e1 to thereby allow the exterior of the first processing chamber 100 and the buffer space S of the blowing mechanism 110e1 to communicate with each other. The supply pipe 110e14 is used to supply a nonreactive gas (e.g., an Ar gas) from a non-illustrated gas supply source into the buffer space S of the blowing mechanism 110e1. Though it is desirable to supply the nonreactive gas so as to improve the uniformity of the mixture of gas molecules (film forming gas) present in the buffer space S, it is not indispensable.

Further, the blowing mechanism 110e1 is also provided with an exhaust pipe 110e15 inserted through the sidewall of the blowing mechanism 110e1 to thereby allow the inside U of the first processing chamber 100 and the buffer space S of the blowing mechanism 110e1 to communicate with each other. Further, an orifice 110e16 is inserted in the exhaust pipe to narrow the passageway.

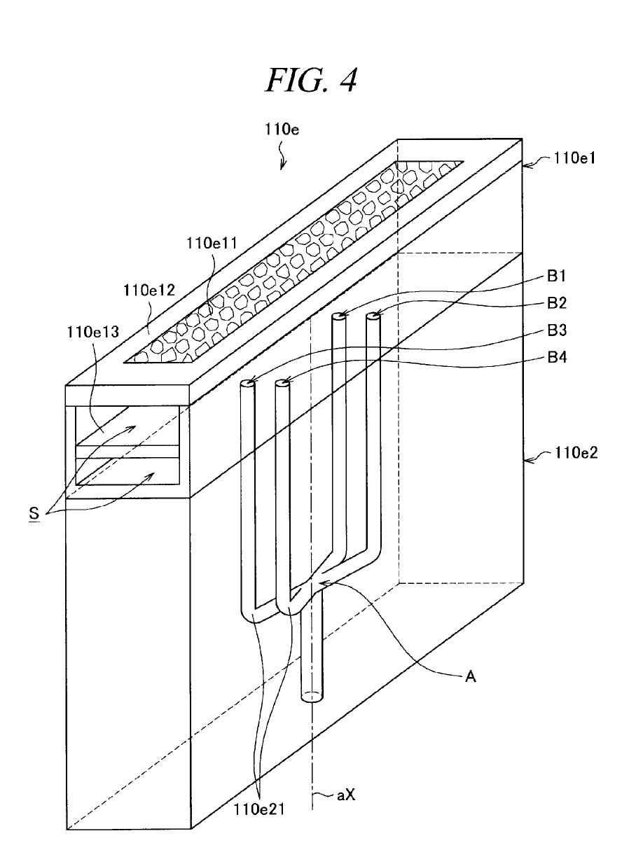

The transport mechanism 110e2 has four transport paths 110e21 formed through the inside thereof after branched from one transport path, as shown in FIG. 4. The distances from a branch portion A to openings B1, B2, B3 and B4 of the four transport paths 110e21 (communication openings between the transport paths 110e21 and the buffer space S) are almost same.

The branched transport paths 110e21 are formed point-symmetrically (in same shapes) about an axis aX with respect to the branch position A of the transport paths 110e21. Further, the plural outlets B1, B2, B3 and B4 of the transport paths 110e21 are arranged in the bottom surface of the blowing vessel 110e at a same distance.

A QCM (Quartz Crystal Microbalance: quartz vibrator) 300 is installed in the vicinity of the opening of the exhaust pipe 110e14 inside the first processing chamber 100 of FIG. 2. The QCM 300 is an example of a second sensor for detecting a generation rate of the mixture of gas molecules exhausted from the opening of the exhaust pipe 110e14, that is, a film forming rate (D/R: deposition rate). Below, the principle of the QCM will be simply explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed in this way is QCM. As can be seen from the equation, a change of the frequency is deemed to be determined based on a change of the elastic constant dependent on the adhered substance; and a thickness dimension of the adhered substance calculated in terms of the quartz density. Thus, the change of the frequency can be calculated in terms of the weight of the deposits.

By using such principle, the QCM 300 outputs a frequency signal ft for detecting a film thickness adhered on the quartz vibrator (film forming rate). The film forming rate detected from the frequency signal ft is used to feedback-control the temperature of each crucible so as to control the vaporization rate of each film forming material contained in the crucible.

Now, the shape and internal configuration of the second processing chamber 200 will be described with reference to FIGS. 1 and 2. The second processing chamber 200 is installed separately from the first processing chamber 100 as mentioned above, and has a substantially rectangular parallelepiped shape and also is provided with prominent portions and recess portions at its bottom portion.

The second processing chamber 200 includes a first vapor deposition source 210a, a second vapor deposition source 210b, a third vapor deposition source 210c, a fourth vapor deposition source 210d, a fifth vapor deposition source 210e and a sixth vapor deposition source 210f.

The first to the sixth vapor deposition sources 210a to 210f are connected with the first to the sixth blowing vessels 110a to 110f via connection pipes 220a to 220f, respectively.

Each vapor deposition source 210 has the same shape and configuration. Thus, the internal configuration of the fifth vapor deposition source 210e will only be explained for example with reference to FIGS. 1 and 2, while omitting description of the other vapor deposition sources 210.

The fifth vapor deposition source 210e includes a first crucible 210e1, a second crucible 210e2 and a third crucible 210e3 as three vapor deposition sources. The first crucible 210e1, the second crucible 210e2 and the third crucible 210e3 are connected with a first connection pipe 220e1, a second connection pipe 220e2 and a third connection pipe 220e3, respectively, and these three connection pipes 220e1 to 220e3 are coupled to each other at a junction portion C after penetrating the processing chamber 200 and connected to the fifth blowing vessel 110e after penetrating the processing chamber 100.

The crucibles 210e1 to 210e3 contain therein different kinds of film forming materials as a film-forming source material, and by setting the temperature of each crucible to a high temperature level of, e.g., about 200 to 500° C., the various kinds of film forming materials are vaporized. The bottom surface of each crucible 210e is in contact with the second processing chamber 200, so that the heat around the bottom surface of each crucible 210e can be discharged out from the prominence portions and recess portions provided at the second processing chamber 200.

Installed at the connection pipes 220e1 to 220e3 outside the second processing chamber (in the atmosphere) are valves 230e1 to 230e3, respectively. By manipulating the opening/closing of each valve 230e, it is controlled whether each film forming material (gas molecules) is supplied into the first processing chamber 100 or not. Further, when replenishing each crucible with the film-forming source material, not only the inside of the second processing chamber 200 but also the inside of the connection pipe 220e is opened to the atmosphere. Accordingly, by closing each valve 230e during the supplement of the film-forming source material, communication with the inside of the connection pipe 220e and the inside of the first processing chamber 100 is cut off, so that the inside of the first processing chamber 100 can be prevented from being opened to the atmosphere and thus the inside of the first processing chamber 100 can be maintained in a preset depressurized state.

Further, the connection pipe 220e (including the first connection pipe 220e1, the second connection pipe 220e2 and the third connection pipe 220e3) connects the vapor deposition source 210 with the blowing vessel 110, functioning as a connection path for transporting the film forming material vaporized from the vapor deposition source 210 toward the blowing vessel 110.

Orifices 240e2 and 240e3 respectively provided with a hole having a diameter of about 0.5 mm are inserted in the second and third connection pipes 220e2 and 220e3, respectively, inside the second processing chamber.

Supply pipes 210e11, 210e21, and 210e31 are installed at the crucibles 210e1, 210e2 and 210e3, respectively, in a manner that they are inserted through the sidewall of each crucible, thus allowing the inside T of the second processing chamber 200 to communicate with the insides R1, R2 and R3 of the crucibles. The supply pipes 210e11, 210e21 and 210e31 are used to supply a nonreactive gas (e.g., an Ar gas) into the inside of each crucible from a non-illustrated gas supply source. The supplied nonreactive gas functions as a carrier gas which carries each film-forming gas (gas molecule) present in the insides R1, R2 and R3 to the blowing mechanism 110e1 through the connection pipe 220e and the transport path 110e21.

Further, exhaust pipes 210e12, 210e22 and 210e32 are installed at the crucibles 210e1, 210e2 and 210e3, respectively, in a manner that they are inserted through the sidewall of each crucible 210e, thus allowing the inside T of the processing chamber 200 to communicate with the insides R1, R2 and R3 of each crucible 210e. Orifices 210e13, 210e23 and 210e33 are inserted in the exhaust pipes 210e12, 210e22, and 210e32, respectively. Each of the orifices 210e13 to 210e33 is provided with a central opening having a diameter of about 0.1 mm, and they function to narrow a passageway of the exhaust pipes 210e12 to 210e32 (see FIG. 4).

In the inside T of the second processing chamber 200, QCMs 310a to 310c are installed in the vicinity of the exhaust pipes 210e12 to 210e32, respectively. The QCMs 310a to 310c output frequency signals f1 to f3 to detect respective vaporization rates of film forming materials exhausted from the openings of the exhaust pipes 210e12 to 210e32. A QCM 310 is one example of a first sensor.

Heaters 400 and 410 are embedded in each vapor deposition source 210e to control the temperature of the vapor deposition source 210e. For example, in the first crucible 210e1, a heater 400e1 is buried in its bottom wall and a heater 410e1 is installed in its sidewall. Likewise, in the second and third crucibles 210e2 and 210e3, heaters 400e2 and 400e3 are buried in their bottom walls and heaters 410e2 and 410e3 are installed in their sidewalls, respectively. Each of the heaters 400 and 410 is connected with an AC power supply 600.

A controller 700 includes a ROM 710, a RAM 720, a CPU 730 and an input/output interface (I/F) 740. The ROM 710 and the RAM 720 store therein, for example, data indicating a relationship between the frequency and the film thickness, programs for feedback controlling the heaters, or the like. By using such various data or programs stored in those storage areas, the CPU 730 calculates a generation rate of gas molecules of each film forming material from the frequency signals ft, f1, f2, f3 inputted from the input/output I/F; calculates a voltages to be applied to the heaters 400e1 to 400e3 and the heaters 410e1 to 410e3 based on the calculated generation rate; and transmit the results to the AC power supply 600 as temperature control signals.

The AC power supply 600 applies a preset voltage to the heaters 400 and 410 based on temperature control signals transmitted from a controller 700. Further, the AC power supply 600 applies a preset voltage to the heaters 420 and 430 so as to heat them up to desired temperatures based on predetermined processing conditions.

Further, an O-ring 500 is disposed at a bottom surface of the first processing chamber 100's outer wall through which the connection pipe 220e is inserted, whereby the communication between the atmosphere and the first processing chamber 100 is cut off, and thus the inside of the first processing chamber can be hermetically kept.

Further, O-rings 510 to 530 are installed at a top surface of the second processing chamber 200's outer wall through which the connection pipes 220e1 to 220e3 are inserted, respectively, whereby the communication between the atmosphere and the second processing chamber 200 is cut off, and the inside of the second processing chamber 200 can be hermetically kept. Moreover, the insides of the first and second processing chambers 100 and 200 can be depressurized to preset vacuum levels by a non-illustrated exhaust system.

The target object G is electrostatically attracted and held on a stage (not shown) having a sliding mechanism in an upper region of the first processing chamber 100. As shown in FIG. 1, the substrate G is moved from the first blowing device 110a to the second blowing device 110b, the third blowing device 110c, the fourth blowing device 110d, the fifth blowing device 110e and to the six blowing device 110f (110a→110b→110c→110d→110e→110f) at a preset speed while being located slightly above each of the blowing vessels 110a to 110f separated by the seven partition walls 120. As a result, different films are formed on the target object G in six layers depending on the film forming materials blown out from the respective blowing vessels 110a to 110f. Below, specific operation of the evaporating apparatus 10 during this 6-layer consecutive film forming process will be explained.

(6-Layer Consecutive Film Forming Process)

First, film forming materials used in the 6-layer consecutive film forming process will be described with reference to FIG. 5. FIG. 5 illustrates the state of each layer deposited on the target object G as a result of performing the 6-layer consecutive film forming process by using the evaporating apparatus 10.

First, in the evaporating apparatus, while the target object G is being moved above the first blowing vessel 110a at a certain speed, a film forming material blown out from the first blowing vessel 110a is adhered to the target object G, so that a hole transport layer as a first-layer is formed on the target object G. Then, while the target object G is being moved above the second blowing vessel 110b, a film forming material blown out from the second blowing vessel 110b is adhered to the target object G, so that a non-light emitting layer (electron blocking layer) as a second-layer is formed on the target object G. Likewise, while the target object G is being moved above the third blowing vessel 110c, the fourth blowing vessel 110d, the fifth blowing vessel 110e and the six blowing vessel 110f (110c→110d→110e→110f) in this sequence, a blue light emitting layer as a third-layer, a red light emitting layer as a fourth-layer, a green light emitting layer as a fifth-layer and an electron transport layer as a sixth-layer are formed on the target object G depending on film forming materials blown out from the blowing vessels.

By the 6-layer consecutive film forming process of the evaporating apparatus 10 described above, the six films are consecutively formed within the same chamber (i.e., the first processing chamber 100). Accordingly, throughput can be improved, resulting in enhancement of productivity. Further, since conventional installation of a plurality of processing chambers for the different types of films to be formed becomes unnecessary, scale-up of the apparatus can be prevented, and cost can be reduced.

(Flow of Gas Molecules Inside the Blowing Vessel)

Now, referring to FIG. 2, it will be explained how the gas molecules flow inside the blowing vessel 110 while the film formation process is being performed on the target object G by using the evaporating apparatus 10.

(Transport Path)

The gas molecules (simple substances) of each film forming material vaporized from each of the crucibles 210e1 to 210e3 enter the transport path 110e21 through the connection pipe 220e while being mixed with each other at a junction portion C after passing through the respective connection pipes 220e1 to 220e3. Then, the gas molecules are transported through the four branched transport paths 110e21 formed point-symmetrically in the same shapes from the branch position A, as illustrated in FIG. 4, and then are discharged into the buffer space S from the openings B (B1 to B4) which are equi-spaced at the bottom surface of the buffer space S in the lengthwise and widthwise directions thereof.

In this configuration, the distances from the branch position A of the transport paths to the four branched openings B are all same. Meanwhile, the velocity decrease of the gas molecules due to collision with the wall surface of the transport path 110e21 or other gas molecules during their travel through the transport path 110e21 is in proportion to the length of the transport path 110e21 through which the gas molecules pass. Therefore, the velocity decrease of the gas molecules during their travel through the four transport paths 110e21 having the same lengths becomes substantially equal. Accordingly, the gas molecules can be discharged into the buffer space S from the openings B1 to B4 of the respective transport paths at a substantially same velocity.

Further, since the openings B1 to B4 are equi-spaced, the gas molecules can be discharged into the buffer space S uniformly from the openings B1 to B4 of the respective transport paths. Accordingly, the gas molecules can be discharged uniformly into the buffer space S at the substantially same velocity.

Moreover, the shape of the branched transport paths 110e21 is not limited to the example shown in FIG. 4, but can be modified in various ways as long as their lengths are same and the openings of the branched transport paths 110e21 are equi-spaced with respect to a certain direction of opening surfaces.

(Diffusion Plate)

As stated above, the diffusion plate 110e13 is installed to divide the buffer space S of the blowing vessel into the space at the blowing port 110e11 and the space at the transport path 110e21. In this configuration, the gas molecules discharged into the buffer space S is always made to pass through the diffusion plate 110e13. In this way, by making the gas molecules pass through passageways (holes h) formed inside the diffusion plate 110e13, the gas molecules can be further mixed. In addition, the pressure of the space at the blowing port can be further stabilized by being separated from the space at the transport path by the diffusion plate 110e13.

(Blowing Port with the Metal Porous Member)

The gas molecules moved toward the blowing port side through the diffusion plate 110e13 are blown out from the metal porous member installed at the blowing port 110e11. At this time, since the gas molecules are blown out through the void spaces between the pores formed inside the metal porous member of the blowing port 110e11, the amount of the blown-out gas molecules is limited. Accordingly, among the gas molecules that have been introduced into the buffer space S through the connection path 220e and the transport path after vaporized from the vapor deposition source 210e, gas molecules exceeding a preset amount are not allowed to pass through the blowing port 110e11 of the metal porous member immediately, and they stay in the buffer space S temporarily.

In this way, the gas molecules stay in the buffer space S temporarily such that the pressure of the buffer space S is larger than the pressure (i.e., pressure of a processing chamber U) outside of the blowing vessel 110 and then the stayed gas molecules are blown out from the blowing port. As a result, the buffer space S is maintained at a preset pressure (density) and the gas molecules are mixed during their stay in the buffer space S, so that they become more uniform.

In this way, the gas molecules, which have come into a more uniform state, collide with the wall surface of the flow paths (void spaces between the pores) inside the porous member or other gas molecules when they pass through the porous blowing port 110e11. As a result, the gas molecules are uniformly blown out from the entire surface of the porous blowing port 110e11 in a state in which their directional deflection is low, while their velocity gets reduced. That is, the gas molecules of the film forming materials are blown out from the entire surface of the porous blowing port 110e11 while being kept in the highly uniform state after sufficiently mixed with each other. As a result, the controllability of the film formation increases, so that even in case that the gap between the blowing port 110e11 of the blowing vessel 110e and the target object G is set to be shorter than that in conventional cases, a uniform film with a fine quality can be formed on the target object.

Further, by shortening the gap between the blowing port 110e11 of the blowing vessel 110 and the target object G as stated above, excessive diffusion of the gas molecules blown out from the blowing port 110e11 is suppressed, so that a greater amount of gas molecules can be adhered to the vapor deposition surface of the target object G. Therefore, the material utilization efficiency can be improved, thus enabling reduction of manufacturing cost of a product.

Furthermore, by suppressing the excessive diffusion of the gas molecules as described above, the gas molecules are suppressed from adhering to the other parts inside the processing chamber. Thus, the cleaning cycle for the inside of the processing chamber can be lengthened, so that throughput and productivity can be enhanced.

(Temperature Control Mechanism)

The evaporating apparatus 10 includes a temperature control mechanism for controlling a temperature of the vapor deposition source 210. As shown in FIG. 2, the vapor deposition source 210e includes the heaters 400e and 410e provided for each crucible therein. The heater 400e corresponds to a first temperature control mechanism disposed at each crucible's film forming material accommodating portion (marked by q in FIG. 2), and the heater 410e corresponds to a second temperature control mechanism disposed at each crucible's outlet side (marked by r in FIG. 2) from which the vaporized film forming material is discharged from each crucible. In case that a voltage applied to the heater 410e from the AC power supply 600 is greater than or equal to that applied to the heater 400e, the temperature in the vicinity of the outlet of each crucible can be made higher than or equal to that of the vicinity of the film forming material accommodating portion.

In this way, by setting a temperature of the vicinity of the outlet of each crucible to be higher than or equal to a temperature of the vicinity of the film forming material accommodating portion, it is possible to render a temperature of the portion through which the vaporized film forming material passes higher than or equal to a temperature of the film forming material accommodating portion. As a result, the number of the gas molecules adhered to the vapor deposition source 210, the connection pipe 220 or the like can be further reduced, and thus the material utilization efficiency can be further enhanced.

(Feedback Control by the Temperature Control Mechanism)

In the evaporating apparatus 10 in accordance with the present embodiment, the temperatures of the heaters 400 and 410 are feedback controlled by the controller 700. For this feedback control, each QCM 310 is installed for each crucible of the vapor deposition source 210.

In the evaporating apparatus 10 in accordance with the present embodiment, the vapor deposition source 210 and the blowing vessel 110 are incorporated in the separate chambers. Therefore, the controller 700 detects the vaporization rate of each of the various film forming materials stored in the plurality of crucibles based on vibration numbers (frequencies f1 to f3) of the quartz vibrator outputted from the QCM 310 installed to correspond to each vapor deposition source 210. The controller 700 feedback controls the temperature of each vapor deposition source 210 with high accuracy, based on the vaporization rates thus obtained. In this way, by allowing the vaporization rates of the film forming materials stored in the plurality of vapor deposition source 210 to become approximate to target values more accurately, the controller 700 can control the amount and the mixture ratio of the mixture of gas molecules blown out from the blowing vessel 210 more accurately. As a result, the controllability of the film formation can be increased, and uniform thin films having fine qualities can be formed on the target object G.

Furthermore, in the evaporating apparatus 10 in accordance with the present embodiment, the QCM 300 is installed to correspond to the blowing vessel 110, and the controller 700 calculates the film forming rate of the mixture of gas molecules blown out from the blowing vessel 110 based on the quartz vibrator's vibration number (frequency ft) outputted from the QCM 300.

In the above-stated way, the controller 700 detects the vaporization rates of the film forming materials accommodated in each vapor deposition source 210 and the resultant generation rate of the mixture of gas molecules passing through the blowing vessel 110. As a result, it is possible to detect the loss amount of gas molecules due to their adherence to the connection pipe 220 or the like while they are travelling from the vapor deposition source 210 to the blowing vessel 110 through the connection pipe 220 or the like. With this configuration, by controlling the temperature of each vapor deposition source 210 more accurately based on the vaporization rate of the gas molecules of the various film forming materials (simple substances) and the generation rate of the mixture of the gas molecules, the controllability of the film formation can be improved and more uniform thin films having better qualities can be formed on the target object. Further, though it is desirable to install the QCM 300, it is not indispensable.

(Orifice)

As mentioned above, the orifices 240e2 and 240e3 are inserted in the second and third connection pipes 220e2 and 220e3, respectively. In this way, it may be possible to install an orifice at one position adjacent to the junction portion C on any connection pipe 220 connected with the vapor deposition source based on molecule amounts of the various film forming materials vaporized from the plurality of vapor deposition sources per unit time so as to control the amount of the film forming material passing through the connection pipe 220.

For example, assume that a material A, a material B and Alq₃ (tris(8-hydroxyquinoline)aluminum) are used as film forming materials for the fifth layer, as illustrated in FIG. 5. Further, assume that the molecule amount of the material A vaporized from the first crucible 210e1 per unit time is larger than the molecule amounts of the material B and the Alq₃ vaporized from the second and third crucibles 210e2 and 210e3 per unit time, respectively.

In such case, an internal pressure of the connection path 220e1 through which the material A flows becomes higher than internal pressures of the connection paths 220e2 and 220e3 through which the material B and the Alq₃ flow. Accordingly, in case that the connection paths 220e have the same diameters, the gas molecules tend to be introduced from the connection path 220e1 having the higher internal pressure into the connection paths 220e2 and 220e3 having the lower internal pressures via the junction portion C.

However, the flow paths of the second and third connection pipes 220e2 and 220e3 are narrowed by the orifices 240e2 and 240e3, respectively, so that the passage of the gas molecules of the material A is limited. Accordingly, the gas molecules of the film forming material can be prevented from being introduced toward the connection paths 220e2 and 220e3 having the lower internal pressures from the connection path 220e1 having the higher internal pressure, which may be caused by the reason that the internal pressure of the connection pipe 220e1 through which the material A passes becomes higher than the internal pressures of the connection pipes 220e2 and 220e3 through which the material B and Alq₃ pass. In this way, by introducing the gas molecules of various film forming materials toward the blowing vessel 110 while preventing their backflow, a greater amount of gas molecules can be deposited on the target object G, so that the material utilization efficiency can be further improved.

As stated, based on the molecule amounts of the various film forming materials vaporized from the plurality of vapor deposition sources (crucibles) per unit time, it is desirable to install the orifices at the connection pipe 220e through which the film forming material having the smaller vaporized amounts flows.

However, it may be also possible not to install any orifice 240e at one of the three connection pipes 220e1 to 220e3 regardless of the amounts of the film forming materials per unit time, or it may be also possible to install one orifice at one of the three connection pipes 220e1 to 220e3. Further, though the orifice 240e can be installed at any position (crucible side) adjacent to the junction position C of the connection pipes 220e1 to 220e3, it is desirable to install it closer to the junction position C than to the vicinity of each crucible 210e in order to prevent the backflow of the vaporized film forming material into the vapor deposition source 210e.

Further, in the evaporating apparatus 10 in accordance with the present embodiment, the orifices 110e16, 210e13, 210e23 and 210e33 are installed at the exhaust paths 110e15, 210e12, 210e22 and 210e32 for exhausting a part of each film forming material, provided on the side of the QCM 300 and the QCM 310.

With this configuration, by restricting the amount of gas molecules passing through each exhaust path by using each orifice, the amount of exhausted gas molecules can be reduced. As a consequence, the unnecessary exhaust of the gas molecules of the film forming materials can be suppressed, so that the utilization efficiency of material can be further enhanced.

(Experiments for Investigating Uniformity of Film)

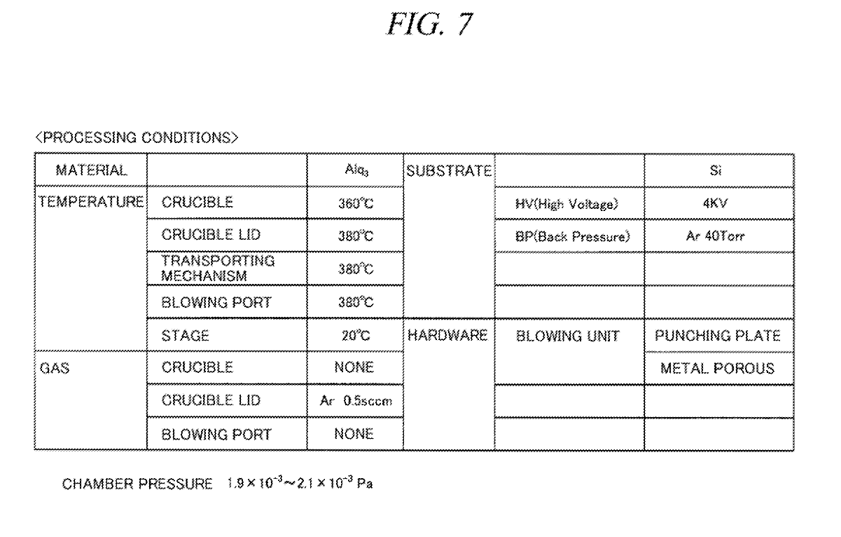

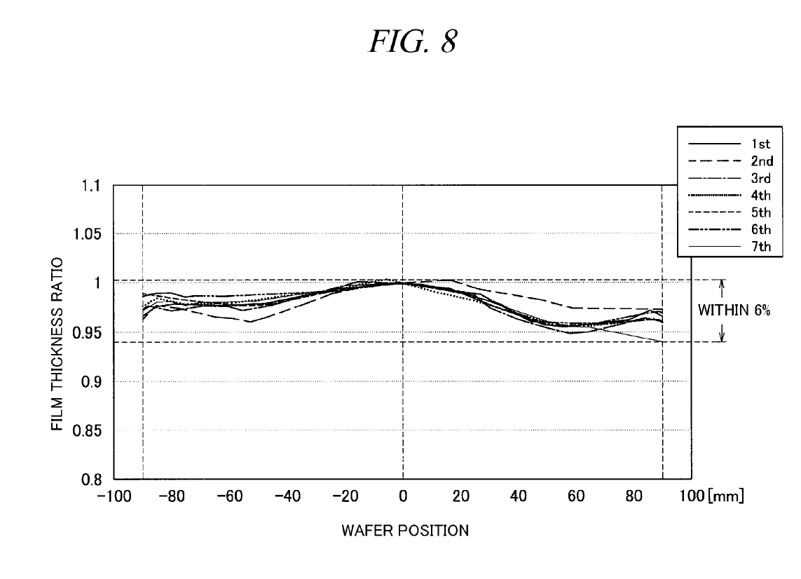

The inventors conducted experiments seven times for investigating the degree of uniformity and the quality of a film obtained by using the evaporating apparatus 10 having the above-described configuration in case that the gap between the blowing port and the target object G is set to about 15 mm. Processing conditions therefor are provided in FIG. 7, and experiment results are provided in FIG. 8.

The processing conditions will be first explained. Alq₃ (tris 8-hydroxyquinoline aluminum) was used as a film forming material, and its flow rate was set to be about 0.5 sccm. As for a temperature condition, to set the temperature of the vicinity of the bottom surface of each crucible 210 (i.e., the temperature of the heater 400e of FIG. 2) and the temperature of the vicinity of a lid of each crucible 210 (i.e., the temperature of the heater 410e) to be about 360° C. and 380° C., respectively, a preset AC voltage was applied to each heater from the AC power supply 600. Further, to set the temperature of the transport mechanism portion (i.e., the transport mechanism 110e2 of FIG. 2) to be about 380° C., an AC voltage was applied to a non-illustrated heater installed in the transport mechanism from the AC power supply 600. An AC voltage was also applied to the heater 420e to set the temperature of the blowing port 110e11 to be about 380° C. Further, the temperature of a stage (not shown) for mounting the target object G thereon was maintained at about 20° C.

In addition, the inventors supplied an argon gas to the vicinity of the lid inside each crucible 210 (that is, to the outlet side of each crucible 210 through which the film forming material is discharged) at a flow rate of about 0.5 sccm as a carrier gas. Meanwhile, no gas was supplied to the blowing port 110e11. A silicon wafer having a size of about 200 mm×80 mm was used as the target object G.

Further, the inventors applied a high voltage HV of about 4 kV to the stage to attract and hold the wafer electrostatically. Moreover, they also supplied the argon gas of about 40 Torr to a rear surface of the wafer to emit the heat of the stage by increasing the back pressure BP of the rear surface of wafer.

The inventors vaporized the Alq₃ gas and blew out the vaporized Alq₃ from the metal porous member of the blowing port 110e11 to thereby adhere it to the wafer under the above-stated processing conditions by using the evaporating apparatus 10. FIG. 8 shows a film thickness ratio (Y axis) at each position along the width direction (X axis) of the silicon wafer of 200 mm. As can be seen from FIG. 8, fine results without deviation could be obtained throughout the seven experiments.

In the experiment results, a silicon wafer's edge portion in the range of about 10 mm from both ends of the silicon wafer of 200 mm is not used as a product. Accordingly, in the following experiment data, the state of films formed within the range of about ±90 mm from the center 0 of the silicon wafer would be evaluated, and in the drawing, data of the range of 10 mm from the both ends of the silicon wafer of 200 mm is omitted.

The experiment results showed that the difference between the maximum and the minimum of the data in the range of ±90 mm from the center 0 of the silicon wafer was just about 6% (i.e., +3%˜−3%), as illustrated in FIG. 8. Thus, the inventors could prove that it is possible to form a uniform film having a fine quality as a product even in case that the gap between the blowing port and the silicon wafer is set to be about 15 mm by using the evaporating apparatus 10 in accordance with the present embodiment.

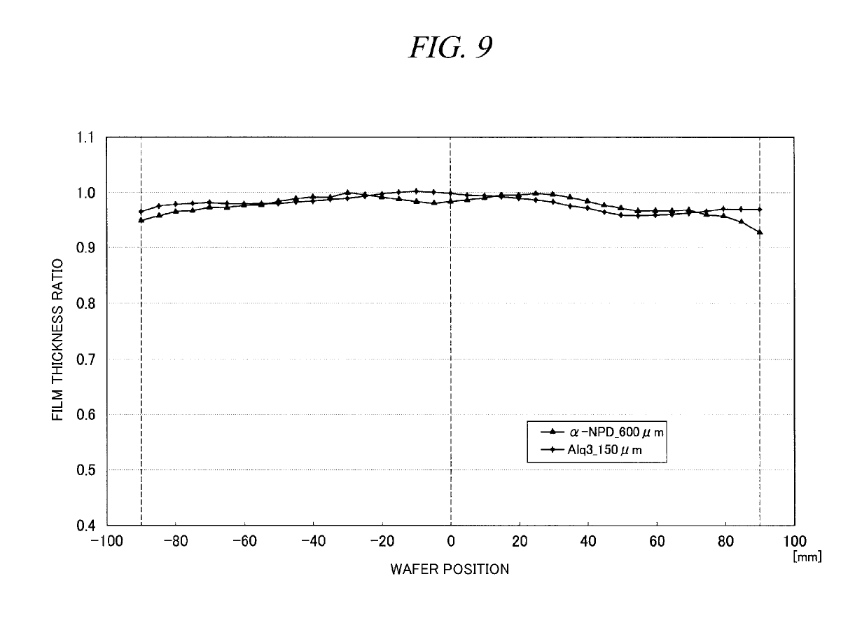

Furthermore, the inventors also conduct an experiment for calculating an optimal porosity of the metal porous member of the blowing port 110e11. That is, they conducted an experiment for investigating a variation of the film thickness ratio on the silicon wafer while changing the porosity of the metal porous member of the blowing port 110e11. FIG. 9 shows a film thickness ratio (Y axis) at each position along the width direction (X axis) of the silicon wafer of 200 mm.

As a result, the inventors could observe that the difference between the maximum and the minimum of the film thickness ratio of the deposited film in the range of ±9 cm from the center 0 of the silicon wafer was just about 7% in both cases of using α-NPD while setting the particle diameter of the metal porous member to be 600 μm, i.e., the porosity to be 97% and using the Alq₃ (an example of an organic material) while setting the particle diameter to be 150 μm, i.e., the porosity to be 87% and fine results without deviation could be obtained. Thus, the inventors could prove that it is possible to form a uniform film having a fine quality by setting the porosity of the metal porous member installed in the blowing port 110e11 of the evaporating apparatus 10 in accordance with the present embodiment to be equal to or lower than about 97%.

In the evaporating apparatus 10 in accordance with the present embodiment described above, by installing the porous body in the blowing port 110e11, the gas molecules can be made to stay in the buffer space S temporarily. Therefore, the gas molecules can be blown out from the porous body uniformly, so that a uniform fine-quality film can be formed on the target object G even in case that the gap between the target object G and the blowing port 110e11 is shortened in comparison with conventional cases.

### Second Embodiment

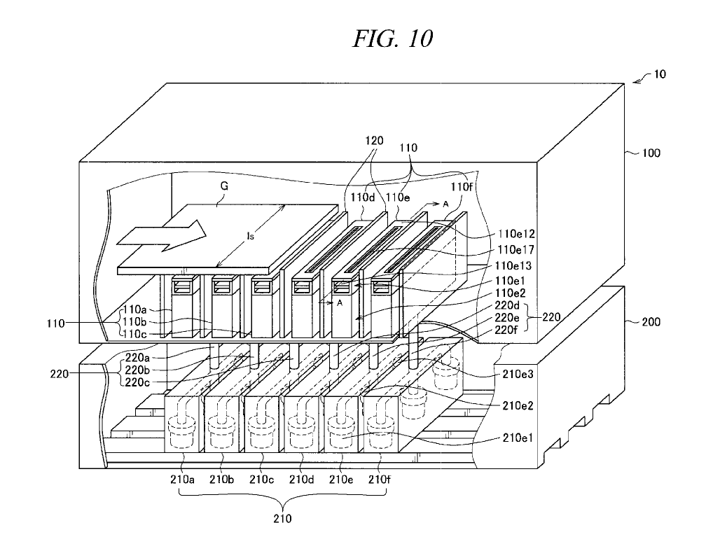

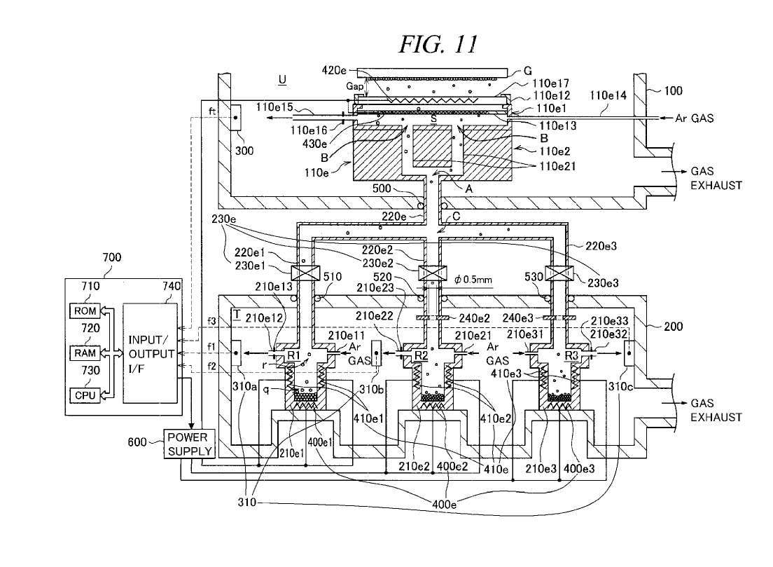

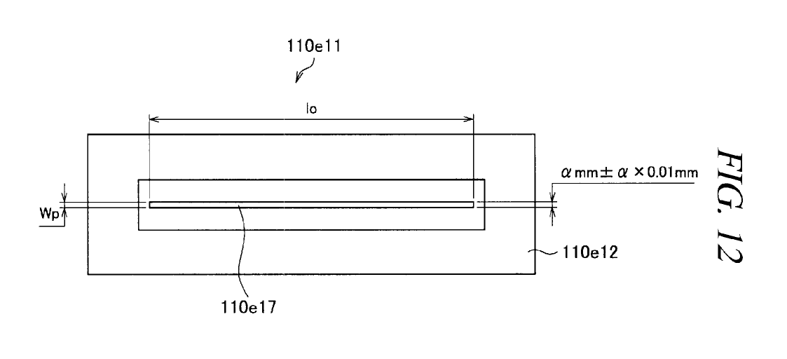

Now, an evaporating apparatus 10 in accordance with a second embodiment of the present invention will be described. The evaporating apparatus 10 in accordance with the second embodiment is different from the evaporating apparatus 10 having the porous body in the blowing port 110e11 of FIG. 2 in accordance with the first embodiment in that a blowing port 110e17 of a blowing vessel 110 is formed in a slit shape, as shown in FIGS. 10 and 11. Accordingly, the evaporating apparatus 10 of the second embodiment will be elaborated based on this difference.

The blowing port 110e17 of the blowing vessel 110 in accordance with this embodiment has a slit-shaped opening of which practical width value Wp falls within the range of α mm±α×0.01 mm when its goal width value Wg is set as α mm, as shown in FIG. 12. The length of the blowing port 110e17 is referred to as lo.

The inventors found optimal values for the width (shorter-side) and the length (longer-side) dimensions of the slit-shaped opening through an experiment. Such experiment result is provided below.

(Optimal Size of the Width of the Slit-Shaped Opening)

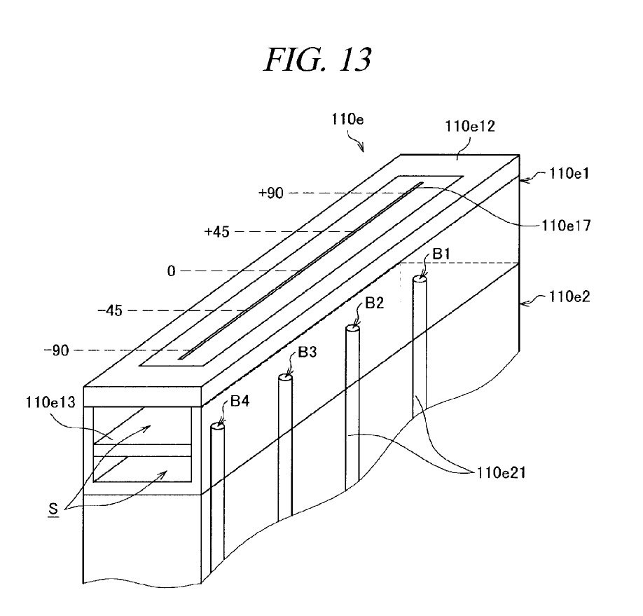

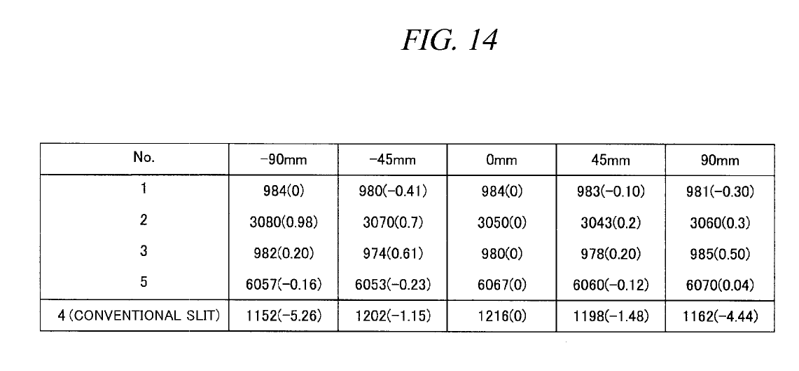

FIG. 14 provides an experiment result of measuring a film thickness at each position (−90, −45, 0, +45, +90) of the slit of the blowing port 110e17 when varying the goal value Wg and the practical value Wp of the slit width shown in FIG. 13. Specifically, α as the goal value Wg in sample Nos. 1, 2, 3, 5, 4 is 1 mm, 3 mm, 1 mm, 1 mm, and 1 mm, respectively, and the practical values thereof are provided in FIG. 14. In the sample No. 5, a slit has a shape gradually enlarged from the inlet side toward the outlet side, wherein the opening width of the inlet of the slit is 1 mm, whereas the opening width of the outlet of the slit is 6 mm. Though the opening width of the slit outlet is shown in FIG. 14, a gas flow rate is controlled by the opening width (1 mm) of the slit inlet. Accordingly, α as the goal value Wg of the sample No. 5 is 1 mm.

Furthermore, values in parentheses in a table are percentages of the deviation from a reference value, supposing a slit position of 0 mm (slit center) is a reference. That is, the values in the parentheses in the table indicate the accuracy of the slit width at each position (−90, −45, 0, +45, +90) with respect to the width at the center position of the slit.

The experiment result shows that the accuracy of the slit width at each position with respect to the slit width α is less than 1% in all of the sample Nos. 1, 2, 3 and 5. Meanwhile, in case of sample No. 4 (conventional slit), the accuracy of the slit width at each position with respect to the slit width a ranges from about 1.5 to 5%.

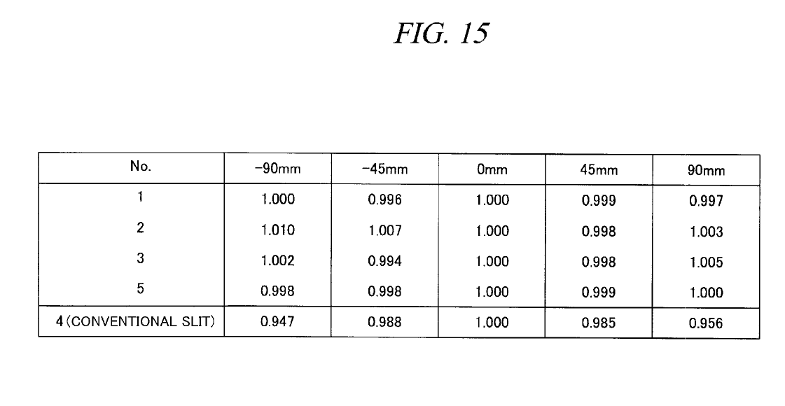

FIG. 15 provides a result of normalizing the above results by setting a value at the slit position of 0 mm as 1. In samples Nos. 1, 2, 3 and 5, differences in film thickness ratios at respective positions on the silicon wafer are stabilized to less than or equal to ±1%. Meanwhile, in case of sample No. 4 (conventional slit), the differences in film thickness ratios at respective positions on the silicon wafer exceed ±5%.

From the above experiment result, the present inventors found out that if the practical value Wp of the width of the slit opening is set to be in the range of α mm±α×0.01 mm (α mm is the goal width value Wg), the difference in the film thickness ratios can be desirably made less than or equal to 1% at each of the different positions on the silicon wafer. From the above experiment results, the inventors found out that the gas molecules of the film forming materials can be uniformly blown out at a low velocity from the slit-shaped blowing port 110e17 if the goal value Wg of the width of the slit-shaped opening is less than or equal to 3 mm.

Based on the above experiment results, the present inventors deemed that the gas molecules of the film forming materials can be uniformly blown out at the low velocity from the slit-shaped blowing port 110e17 in the evaporating apparatus 10 in accordance with the present embodiment due to the following mechanism.

That is, in case that the slit has the above-descried shape, most of the gas molecules present inside the blowing vessel 110 is not allowed to pass through the blowing port 110e17 smoothly but reflected from the inner wall of the blowing vessel 110 and rebounded into the buffer space S. After such movements are repeated, the gas molecules are allowed to be discharged out through the slot of the blowing port 110e17. That is, among the gas molecules that have been introduced into the buffer space S through the connection pipe 220e and the transport path 110e21 after vaporized from the vapor deposition source 210, gas molecules exceeding a preset amount cannot pass through the blowing port 110e17 immediately, and they stay in the buffer space S temporarily. In this way, the pressure (density) inside the buffer space S is maintained higher than the pressure (density) outside the blowing vessel 110. Accordingly, while the gas molecules are staying in the buffer space S, they are mixed with each other to be in a uniform state.

As described, it was proved the controllability of the film formation can be improved, thus enabling to form a uniform fine-quality film on the target object G even in case that the gap between the blowing port 110e17 and the target object G is shortened in comparison with conventional cases.

(Optimal Size of the Length of the Slit-Shaped Opening)

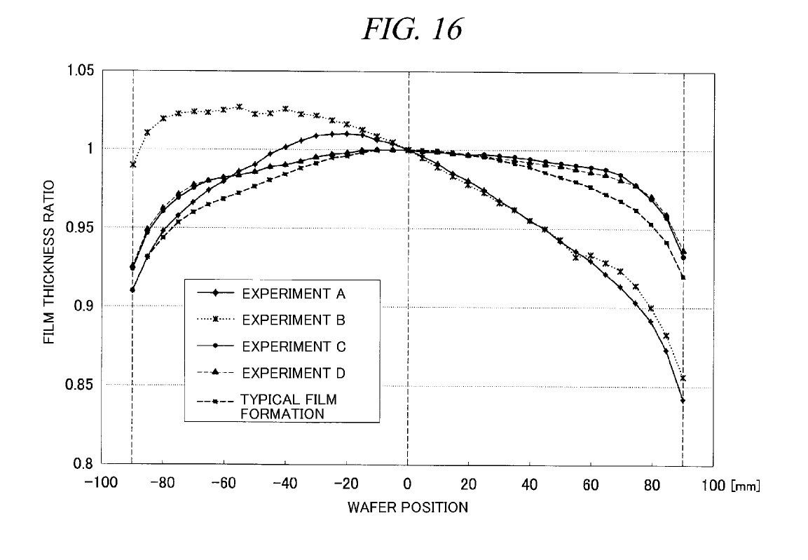

In addition, the present inventors also found out that it is desirable to set the length lo of the slit opening to be longer than the length ls (see FIG. 10) of the silicon wafer, which is positioned above the blowing vessel, in a direction horizontal to the lengthwise direction of the slit opening by at least ls×0.1 mm at both ends of the slit opening. FIG. 16 presents results of experiments conducted by the present inventors to obtain an optimal size of the length of the slit-shaped opening.

In the experiments, the openings B1 to B4 of the four transport paths 110e21 of FIG. 13 were equi-spaced on the bottom surface position of the buffer space S below the slit-shaped blowing port 110e17 in the lengthwise direction thereof. The distance between the openings B was about 58 mm, and the lengths from the openings B1 and B4 to respective end portions of the blowing vessel 110e were about 18 mm, respectively.

In experiment A, a gas was blown out only from the opening B2. In experiment B, a gas was blown out only from the opening B1. In experiments C and D, gases were blown out from the openings B1 and B4. Further, the length lo of the slit was set to be equal to the width of the silicon wafer in a typical film formation experiment shown in FIG. 16, whereas the length lo of the slit was set to be longer than the width of the target object (the length ls of the target object of FIG. 10=200 mm) by ls×0.1 mm (here, by 20 mm) at both ends of the slit, i.e., the length lo was set to be about 240 mm in the experiments A to D.

As a result, the present inventors found out that a more uniform film can be formed when the length lo of the slit is longer than the length ls of the silicon wafer at both ends of the slit by ls×0.1 mm, in comparison with the typical film formation in which the slit width is equal to the width of the silicon wafer. Accordingly, it was proved that by optimizing the slit shape as described above, the controllability of the film formation improves, so that a fine-quality uniform film can be formed on the target object G even in case the gap between the blowing port 110e17 and the target object G is shortened in comparison with conventional cases.

Furthermore, since the gap between the blowing port 110e17 and the target object G is short as 15 mm, the gas molecules blown out from the blowing port 110e17 are hardly diffused and adhered to the target object G. In this regard, it can be proved that uniformity of film formation can be further improved just by setting the slit length lo to be longer than the length ls of the target object G by ls×0.1 mm at both ends of the slit.

Furthermore, the present inventors also found out that better film formation can be achieved by blowing out the gas at a position distanced inward from the end portion of the blowing port 110e17 by about 10% based on the fact that more uniform film formation was achieved in the experiments C and D in comparison with the experiments A and B.

As described above, in the evaporating apparatus 10 in accordance with each embodiment, the structure of the blowing port is formed in the preset shapes. As a result, the controllability of the film formation can be improved, so that the material utilization efficiency can be enhanced, while reducing manufacturing cost of a product.

Furthermore, though the above-stated experiment results were obtained by using the silicon wafer, the target object of the film formation may be a glass substrate. In such case, the size of the glass substrate capable of being processed by the evaporating apparatus 10 is about 730 mm×920 mm or greater and, for example, may be a G4.5 substrate size of about 730 mm×920 mm (in-chamber size: about 1000 mm×1190 mm) or a G5 substrate a size of about 1100 mm×1300 mm (in-chamber size: about 1470 mm×1590 mm).

Further, as another example of the sensor used in the feedback control in each embodiment, there can be employed an interferometer (e.g., a laser interferometer) for detecting a film thickness of a target object by, e.g., irradiating light outputted from a light source onto a top surface and a bottom surface of a film formed on the target object and observing and analyzing an interference fringe generated by a difference in optical paths of the two reflected beams.

Further, another example of a flow path adjusting member for adjusting the flow paths of the connection pipes or the exhaust paths in each embodiment may be a variable opening valve for adjusting a flow path of a pipe by varying an opening degree of a valve.

Further, it may be possible to install a coolant supply source (not shown) instead of the power supply 600 disposed outside the evaporating apparatus 10 and embed a coolant supply path (not shown) inside the wall surface of the second processing chamber 200 instead of the heaters 400 and 410 of FIG. 2 as a temperature control mechanism. In such configuration, the film forming material accommodating portion of the vapor deposition source 210 can be cooled by supplying and circulating a coolant through the coolant supply path from the coolant supply source.

It may be also possible to cool the film forming material accommodating portion by directly blowing out a coolant such as air supplied from the coolant supply source toward the vicinity of the film formation material accommodating portion without installing the coolant supply path.

In the above-described embodiment, the operations of the respective components are interrelated and can be substituted with a series of operations in consideration of such interrelation. By the substitution, the embodiment of the evaporating apparatus can be used as an embodiment of a method of using the evaporating apparatus, and the embodiment of the control apparatus of the evaporating apparatus can be used as an embodiment of a control method for the evaporating apparatus.

Further, by substituting the operation of each component with the process of each component, the embodiment of the control method of the evaporating apparatus can be used as an embodiment of a program for controlling the evaporating apparatus and an embodiment of a computer readable storage medium storing the program therein.

The above description of the present invention is provided for the purpose of illustration, and it would be understood by those skilled in the art that various changes and modifications may be made without changing technical conception and essential features of the present invention. It shall be understood that all modifications and embodiments conceived from the meaning and scope of the claims and their equivalents are included in the scope of the present invention.

For example, in the evaporating apparatus 10 in accordance with the above-described embodiment, an organic EL material in the form of powder (solid) is used as the film forming material, and an organic EL multi-layer film forming process is performed on the target object G. However, the evaporating apparatus in accordance with the present invention can also be employed in a MOCVD (Metal Organic Chemical Vapor Deposition) method for depositing a thin film on a target object by decomposing a film forming material vaporized from, e.g., a liquid organic metal on the target object heated up to about 500 to 700° C. As described, the evaporating apparatus in accordance with the present invention may be used as an apparatus for forming an organic EL film or an organic metal film on the target object by vapor deposition by using an organic EL film forming material or an organic metal film forming material as a source material.

Further, in the evaporating apparatus in accordance with the embodiments of the present invention, the plurality of vapor deposition sources and the plurality of blowing vessels are accommodated in the first and the second processing chamber separately. However, it may be also possible to accommodate the vapor deposition sources and the blowing vessels in the same chamber.

1. An evaporating apparatus comprising:
a vapor deposition source for vaporizing a film forming material which is a source material for a film formation;
a transport path connected with the vapor deposition source via a connection path, for transporting the film forming material vaporized from the vapor deposition source;
a blowing vessel having a blowing port connected with the transport path, for blowing out the film forming material transported through the transport path from the blowing port; and
a processing chamber for performing the film formation on a target object with the blown-out film forming material,
wherein the blowing vessel has a buffer space therein, and blows out the film forming material from the blowing port after the film forming material passes through the buffer space such that a pressure in the buffer space of the blowing vessel becomes higher than a pressure outside the blowing vessel.

2. The evaporating apparatus of claim 1, wherein the blowing port is formed of a porous body.

3. The evaporating apparatus of claim 1, wherein the blowing port has a practical width Wp in a range of α mm±α×0.01 mm when a goal width Wg of a shorter-side of the blowing port is set as α mm, and a length lo of a longer-side of an opening of the blowing port, the length lo being longer than a length ls of the target object, which is positioned above the blowing vessel, in a direction horizontal to a lengthwise direction of the opening by at least ls×0.1 mm at both ends of the blowing port.

4. The evaporating apparatus of claim 1, wherein the transport path is branched into a plurality of transport paths, and the branched transport paths have same lengths.

5. The evaporating apparatus of claim 4, wherein openings of the branched transport paths are equi-spaced.

6. The evaporating apparatus of claim 4, wherein the branched transport paths are formed point-symmetrically with respect to a branch position of the transport paths.

7. The evaporating apparatus of claim 1, further comprising:
a diffusion plate which partitions the buffer space of the blowing vessel into a blowing port side space and a transport path side space and allows the film forming material to pass therethrough.

8. The evaporating apparatus of claim 7, wherein the diffusion plate is a partition plate formed of a porous body or a partition plate provided with a number of holes.

9. The evaporating apparatus of claim 1, wherein each of the blowing port and the diffusion plate is made of a conductive member.

10. The evaporating apparatus of claim 9, wherein the blowing port and the diffusion plate include respective temperature control mechanisms for controlling temperatures of the blowing port and the diffusion plate.

11. The evaporating apparatus of claim 1, wherein the vapor deposition source includes a temperature control mechanism for controlling a temperature of the vapor deposition source.

12. The evaporating apparatus of claim 11, wherein the temperature control mechanism of the vapor deposition source includes a first temperature control mechanism and a second temperature control mechanism,
the first temperature control mechanism is disposed at a film forming material accommodating portion of the vapor deposition source to maintain a temperature of the film forming material accommodating portion to a predetermined temperature, and
the second temperature control mechanism is disposed at a vapor deposition source's outlet, from which the film forming material is discharged to maintain a temperature of the outlet to be higher than or equal to the temperature of the film forming material accommodating portion.

13. The evaporating apparatus of claim 1, wherein more than one said vapor deposition source is installed; different kinds of film forming materials are accommodated in the vapor deposition sources, respectively; connection paths respectively connected with the vapor deposition sources are coupled at a preset junction position; and based on the amounts of the different kinds of film forming materials vaporized from the vapor deposition sources per unit time, a flow path adjusting member is installed in one of the connection paths at an upstream position of the preset junction position to control a flow path of said one connection path.

14. The evaporating apparatus of claim 13, wherein based on the amounts of the different kinds of film forming materials vaporized from the vapor deposition sources per unit time, the flow path adjusting member is installed in the connection path through which the film forming material having a low vaporization rate per unit time passes.

15. The evaporating apparatus of claim 1, wherein more than one said blowing vessel is installed, and
the processing chamber accommodates the blowing vessels therein, and a plurality of film forming processes is consecutively performed on the target object with the film forming materials blown out from the respective blowing vessels in the processing chamber.

16. The evaporating apparatus of claim 1, wherein the processing chamber forms an organic EL film or an organic metal film on the target object by vapor deposition by using an organic EL film forming material or an organic metal film forming material as a source material.

17. The evaporating apparatus of claim 1, wherein more than one said vapor deposition source is installed, and
a plurality of first sensors corresponding to the vapor deposition sources is disposed to detect respective vaporization rates of film forming materials accommodated in the vapor deposition sources.

18. The evaporating apparatus of claim 17, wherein a second sensor corresponding to the blowing vessel is disposed to detect a film forming rate of the film forming material blown out from the blowing vessel.

19. The evaporating apparatus of claim 2, wherein the porous body of the blowing port has a porosity equal to or less than about 97%.

20. The evaporating apparatus of claim 3, wherein the α mm as the goal width value Wg of the blowing port is set to be equal to or smaller than about 3 mm.

21. A control apparatus for controlling the evaporating apparatus as claimed in claim 17, wherein the control apparatus feedback controls a temperature of a temperature control mechanism installed at each vapor deposition source based on the respective vaporization rates of the film forming materials detected by the first sensors.

22. A control method for controlling the evaporating apparatus as claimed in claim 17, wherein the control method feedback controls a temperature of a temperature control mechanism installed at each vapor deposition source based on the respective vaporization rates of the film forming materials detected by the first sensors.

23. A method for using an evaporating apparatus as claimed in claim 1, the method comprising:
vaporizing the film forming material accommodated in the vapor deposition source;
passing the vaporized film forming material through the buffer space installed in the blowing vessel via the connection path and the transport path;
blowing out the film forming material, which has passed through the buffer space, from the blowing port installed in the blowing vessel such that a pressure in the buffer space of the blowing vessel becomes higher than a pressure outside the blowing vessel; and
performing the film formation on the target object with the blown film forming material in the processing chamber.

24. A method for manufacturing a blowing port provided in a blowing vessel for blowing out a film forming material vaporized from a vapor deposition source,
wherein the method makes a shape of the blowing port such that a practical width Wp is in a range of α mm±α×0.01 mm when a goal width Wg of a shorter-side of a slit-shaped opening of the blowing port is set as α mm, and a length lo of a longer-side of the opening is longer than a length ls of a target object in a direction horizontal to a lengthwise direction of the opening by at least ls×0.1 mm at both ends of the opening.
